(19) United States
(12) Patent Application Publication
(10) Pub. No.: US 2025/0272823 A1
(43) Pub. Date: Aug. 28, 2025

(54) INTERFEROMETRIC PHASE ERROR CORRECTION USING A NEURAL NETWORK

(71) Applicant: KLA Corporation, Milpitas, CA (US)

(72) Inventor: Taishi Zhang, Singapore (SG)

(21) Appl. No.: 18/590,876

(22) Filed: Feb. 28, 2024

(51) Int. Cl. G06T 7/00; G01B 9/02015

(52) U.S. Cl. CPC G06T 7/0008; G01B 9/0203; G06T 2207/20084; G06T 2207/30148

(57) ABSTRACT

A workpiece is disposed on a stage in an interferometer. Measurements are taken of the workpiece using the interferometer. An image of a surface of the workpiece is generated from the measurements. Phase error is removed from the image with a neural network operated using the processor. The neural network can be a generative adversarial network.

### FIELD OF THE DISCLOSURE

This disclosure relates to error reduction during workpiece metrology.

### BACKGROUND OF THE DISCLOSURE

Interferometers are used as metrology tools, where workpiece surface information is encoded in the phase of interferogram. Interferometers are commonly used in the semiconductor industry to measure aspects of semiconductor wafers. Typical error sources, such as light intensity variation, wafer vibration, detector response linearity, or imperfection of a phase extraction algorithm, can leave interferogram-like error patterns on a decoded wafer surface map. This affects precision of flatness metrics such as site front least squares range (SFQR). An exemplary process to determine SFQR is shown in FIG. 1.

Due to the nature of raw data with an interferogram, error is encoded in the form of interferogram fringes. This error can be printed into downstream maps, such as a thickness map. This is referred as fringe print-through (FPT) error and is an error source that affects precision with several critical metrics such as SFQR. This is shown in FIG. 2.

Several techniques have been tried to reduce FPT, but improved systems and techniques are needed.

### BRIEF SUMMARY OF THE DISCLOSURE

An interferometer is provided in a first embodiment. The interferometer includes a light source that generates a beam of light; a beam splitter in a path of the beam of light; a reference flat in a path of the beam of light from the beam splitter; a stage configured to hold a workpiece in a path of the beam of light from the beam splitter; a detector configured to receive light from the workpiece; and a processor in electronic communication with the detector. The processor is configured to run a neural network that removes phase error from an image generated using information from the detector. The workpiece can be a semiconductor wafer. The neural network can be a generative adversarial network.

A method is provided in a second embodiment. The method includes disposing a workpiece on a stage in an interferometer. Measurements of the workpiece are taken using the interferometer. An image of a surface of the workpiece is generated from the measurements using a processor. Phase error is removed from the image with a neural network operated using the processor. The workpiece can be a semiconductor wafer. The neural network can be a generative adversarial network.

A non-transitory computer-readable storage medium is provided in a third embodiment. The non-transitory computer-readable storage medium includes one or more programs for executing the following steps on one or more computing devices. The steps can include receiving information about a surface of a workpiece from an interferometer; generating an image of the surface of the workpiece using the information; and removing phase error from the image with a neural network. The workpiece can be a semiconductor wafer. The neural network can be a generative adversarial network.

The neural network can be trained using examples of two thickness maps superimposed on each other, such as those measured using different tools.

### DESCRIPTION OF THE DRAWINGS

For a fuller understanding of the nature and objects of the disclosure, reference should be made to the following detailed description taken in conjunction with the accompanying drawings, in which:

FIG. 1 is a diagram of an exemplary process to determine SFQR;

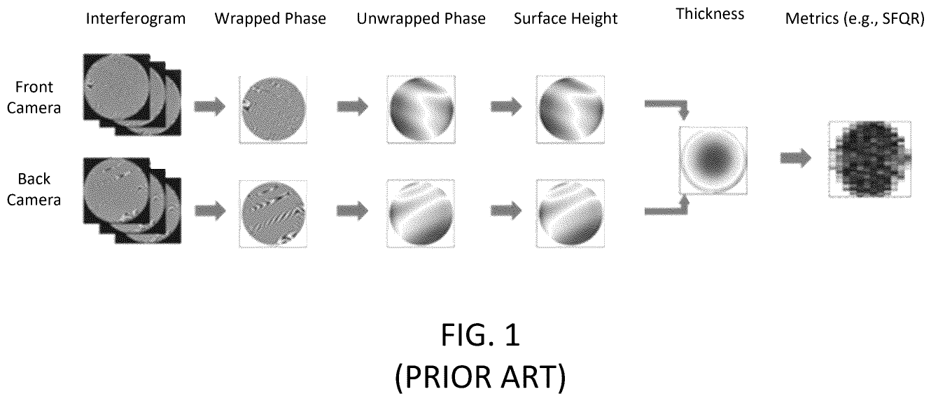

FIG. 2 shows an exemplary interferogram and corresponding thickness precision map;

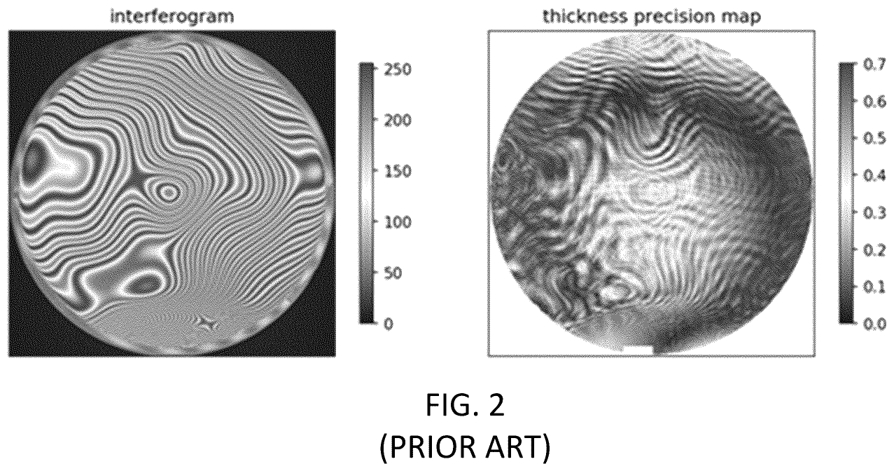

FIG. 3 is an embodiment of an interferometer in accordance with the present disclosure;

FIG. 4 includes two examples of FPT;

FIG. 5 is a flowchart illustrating an embodiment of operation of the neural network in accordance with the present disclosure;

FIG. 6 illustrates an embodiment of a GAN in accordance with the present disclosure;

FIG. 7 includes a variety of exemplary thickness maps;

FIG. 8 illustrates FPT correction using an embodiment in accordance with the present disclosure;

FIG. 9 illustrates precision improvement using an embodiment in accordance with the present disclosure;

FIG. 10 illustrates precision improvement in flatness metrics using an embodiment in accordance with the present disclosure;

FIG. 11 illustrates an exemplary reduction of FPT noise using an embodiment in accordance with the present disclosure; and

FIG. 12 illustrates another exemplary reduction of FPT noise using an embodiment in accordance with the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

Interferometers are metrology tools used in the semiconductor industry. Workpiece (e.g., semiconductor wafer) surface information is wrapped in the phase of the interferogram. Due to the nature of data with an interferogram, phase error and subsequent wafer surface error are encoded in the form of fringes. This error is a source for precision and matching of several critical metrics such as SFQR. In the embodiments disclosed herein, a neural network-based technique can detect and remove such fringe errors. First, a generative adversarial network (GAN) model is trained to learn signatures of the fringe error through large amount of synthesized (raw, clean) pairs that represents wafer surface maps that only differ in presence and absence of fringe error. Then the trained neural network is applied on the raw wafer surface maps with fringe error to remove the fringe error. Improved measurement precision has been demonstrated using this technique.

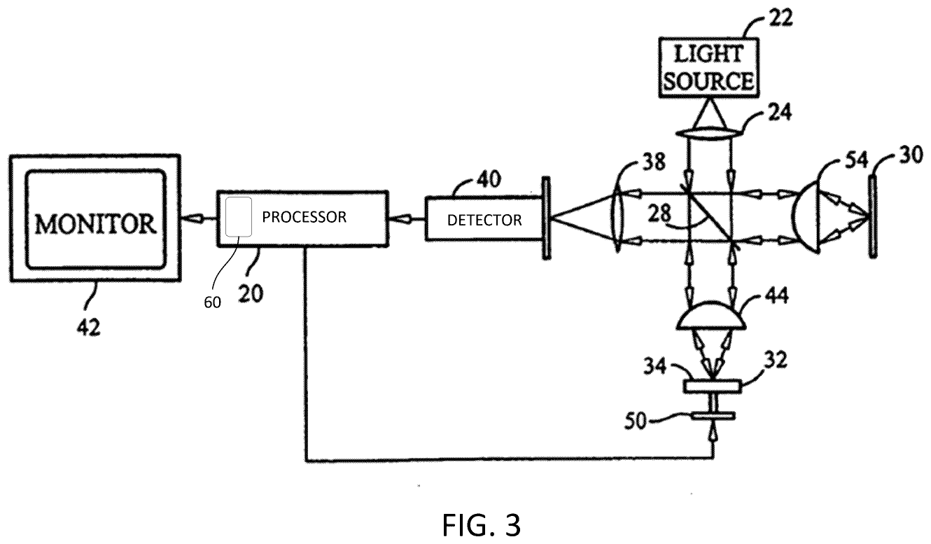

FIG. 3 is an interferometer. While a Michelson interferometer is illustrated, the embodiments disclosed herein can apply to any other type of interferometer, such as a Fizeau, Mirau, Linnik, or Twyman-Green interferometer.

As shown in FIG. 3, the interferometer is controlled by a processor 20, which coordinates the operation of a white light or incoherent light source 22 with other components of the system. The white light from the source 22 is supplied through a collimating lens 24 to a beam splitter 28 along the path of the light, from which the light is separated into two paths. One path goes to a reference flat 30 and the other path goes to the workpiece 32.

The reflected light beams from both the topmost surface 34 and underneath surfaces of the workpiece 32 are directed by the beam splitter 28 to an imaging lens 38, which supplies, simultaneously, multiple interferograms to a detector 40, such as a CCD camera. The detector 40 additionally may include a frame grabber (not shown) for storing images detected by the detector or the processor 20 may be configured to provide this function. The images obtained by the detector 40 are supplied to the processor 20 for processing to produce the desired profiles in a suitable form for display on a monitor 42 or for storage for subsequent utilization.

The processor 20 can provide the step-by-step positioning for each frame of analysis in synchronization with the operation of the detector 40 using a suitable pusher or drive mechanism 50. The pusher mechanism 50 is illustrated in FIG. 3 as moving the workpiece 32 toward and away from the reference flat 30. A piezo-electric pusher, pneumatic pusher, or other suitable mechanical pusher may be employed for this purpose.

Processor 20 is coupled to elements of the interferometer. Processor 20 typically comprises a programmable processor, which is programmed in software and/or firmware to carry out the functions that are described herein, along with suitable digital and/or analog interfaces for connection to the other elements of the interferometer. Alternatively or additionally, processor 20 comprises hard-wired and/or programmable hardware logic circuits, which carry out at least some of the functions of the processor 20. Although processor 20 is shown in FIG. 3, for the sake of simplicity, as a single, monolithic functional block, in practice the processor 20 may comprise multiple, interconnected control units, with suitable interfaces for receiving and outputting the signals that are illustrated in the figures and text herein. Program code or instructions for the processor 20 to implement various methods and functions disclosed herein may be stored in readable storage media, such as a memory.

It should be noted that instead of moving the workpiece 32 with respect to the reference flat 30, the pusher 50 can be mechanically coupled (by a coupling not shown) to the reference flat 30 to move that surface relative to the surfaces of the workpiece 32. Either the workpiece 32 or the reference flat 30 may be moved in parallel planes with respect to one another to produce the repeated measurements or vertical scanning for each of the positions over which the complete scan is made.

The interferometer of FIG. 3 uses identical microscope objective lenses, with the lens 44 being duplicated by another lens 54 provided with inputs from the beam splitter 28. The lens 54 then focuses on a reference flat (mirror) 30, whereas the lens 44 is used to focus on the workpiece 32. The reflected images are gathered and supplied by the beam splitter 28 to the imaging lens 38 for the detector 40. The processor 20 then processes the information.

A neural network 60 can be operated using the processor 20 or a different processor. While the neural network 60 is illustrated as using the processor 20, a separate processor 20 also can be used. The processor 20 can be, for example, a graphics processing unit (GPU). Phase error can be removed from an image using the neural network 60. In a particular example, fringe is removed from the image by the neural network 60. The fringe can be caused by phase error and subsequent wafer surface error.

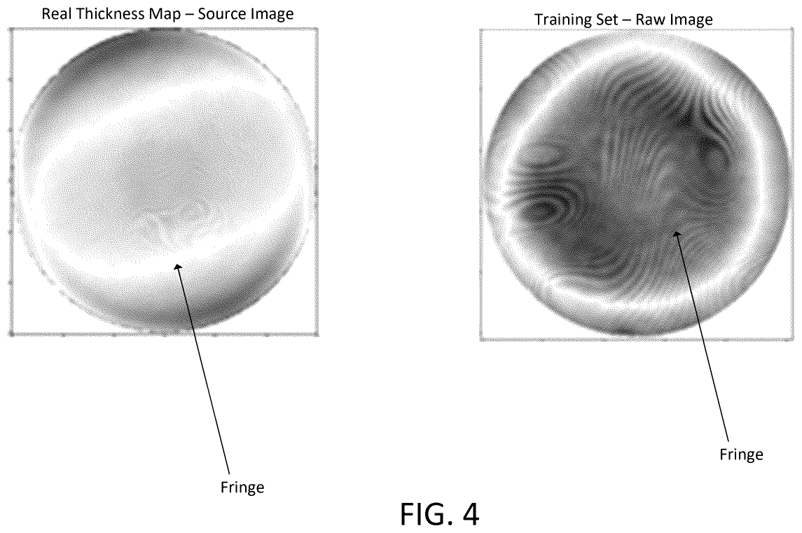

The neural network method for FPT detection/correction resembles human vision for pattern recognition. In the images of FIG. 4, two thickness maps are shown as example. FPT (the curvy fringe pattern) can be observed. A neural networks can learn and remove the fringe error on measured surface, which assumes the actual surfaces to be measured does not exhibit such patterns, which is true for wafer manufacturing.

The GAN model can be trained using workpiece surface image pairs in raw, corrected format. The two images in the pair only differ in terms of the fringe error to be corrected. For in-line usage, a raw wafer surface is provided to the GAN, which generates a corrected surface based on the mapping learned during training. Different wafer surfaces can be superimposed at random weights during this process.

Rooted in neural network technology, deep learning is a probabilistic graph model with many neuron layers, commonly known as a deep architecture. Deep learning technology processes the information such as image, text, voice, and so on in a hierarchical manner. In using deep learning in the present disclosure, feature extraction is accomplished automatically using learning from data. For example, aspects of the image can be removed and/or corrected using the deep learning classification module based on the one or more extracted features.

Generally speaking, deep learning (also known as deep structured learning, hierarchical learning or deep machine learning) is a branch of machine learning based on a set of algorithms that attempt to model high level abstractions in data. In a simple case, there may be two sets of neurons: ones that receive an input signal and ones that send an output signal. When the input layer receives an input, it passes on a modified version of the input to the next layer. In a deep network, there are many layers between the input and output, allowing the algorithm to use multiple processing layers, composed of multiple linear and non-linear transformations.

Deep learning is part of a broader family of machine learning methods based on learning representations of data. An observation (e.g., a feature to be extracted for reference) can be represented in many ways such as a vector of intensity values per pixel or in a more abstract way like a set of edges, regions of particular shape, etc. Some representations are better than others at simplifying the learning task (e.g., face recognition or facial expression recognition). Deep learning can provide efficient algorithms for unsupervised or semi-supervised feature learning and hierarchical feature extraction.

In an embodiment, the deep learning model is configured as a neural network. In a further embodiment, the deep learning model may be a deep neural network with a set of weights that model the world according to the data that it has been fed to train it. Neural networks can be generally defined as a computational approach based on a relatively large collection of neural units loosely modeling the way a biological brain solves problems with relatively large clusters of biological neurons connected by axons. Each neural unit is connected with many others, and links can be enforcing or inhibitory in their effect on the activation state of connected neural units. These systems are self-learning and trained rather than explicitly programmed and excel in areas where the solution or feature detection is difficult to express in a traditional computer program.

Neural networks typically include multiple layers, and the signal path traverses from front to back. The goal of the neural network is to solve problems in the same way that the human brain would, although several neural networks are much more abstract. Modern neural network projects typically work with a few thousand to a few million neural units and millions of connections. The neural network may have any suitable architecture and/or configuration known in the art.

GANs provide generative modeling using deep learning methods, such as convolutional neural networks. Generative modeling is an unsupervised learning task in machine learning that involves automatically discovering and learning the regularities or patterns in input data so that the model can be used to generate or output new examples that plausibly could have been determined from the original dataset.

GANs train a generative model by framing the problem as a supervised learning problem with two sub-models. First, there is a generator model that is trained to generate new examples. Second, there is a discriminator model that tries to classify examples as either real (from the domain) or fake (generated). The two models are trained together in a zero-sum game (i.e., adversarial) until the discriminator model is fooled enough that the generator model is generating plausible examples.

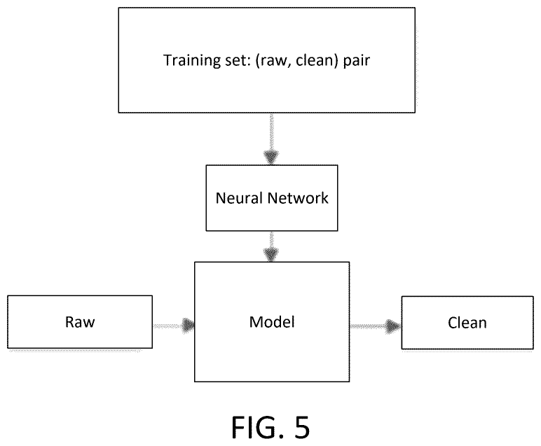

The neural network method for FPT detection/correction resembles human vision for pattern recognition. In the images of FIG. 4, a real thickness map is shown as example, where FPT (in curvy fringe pattern) can be observed. The working flow of a neural network is shown in FIG. 5. In the first step, the neural network is trained by large amount of (raw, clean) image pairs which includes/excludes the FPT error to be corrected. The neural network is a model trained to map between a raw image to a clean image. In the second step, a raw image from the test set is fed into the neural network. The output is a clean image of a workpiece with reduced fringe or no fringe.

The neural network adapts a GAN architecture. The GAN can include two competing networks named Generator (G) and Discriminator (D). The generator may be a U-net, which takes a raw image and generates a fake image to imitate the clean image. The discriminator may be a binary classification network that tries to tell whether the input clean image is real or fake. With both competing networks under evolution together, a generated fake clean image will eventually look true to the real clean image. The generator can work as a pixel-to-pixel translator from raw image to the clean image, such as Pix2Pix.

Pix2Pix is a GAN model designed for general purpose image-to-image translation. The Pix2Pix model is a conditional GAN. Generation of the output image is conditional on an input, such as a source image. The discriminator is provided with a source image and the target image and determines whether the target is a plausible transformation of the source image. The generator is trained via adversarial loss, which encourages the generator to generate plausible images in the target domain. The Pix2Pix GAN can perform image-to-image translation tasks like generating an image from a different image (e.g., a detailed image from a sketch, design, or blueprint).

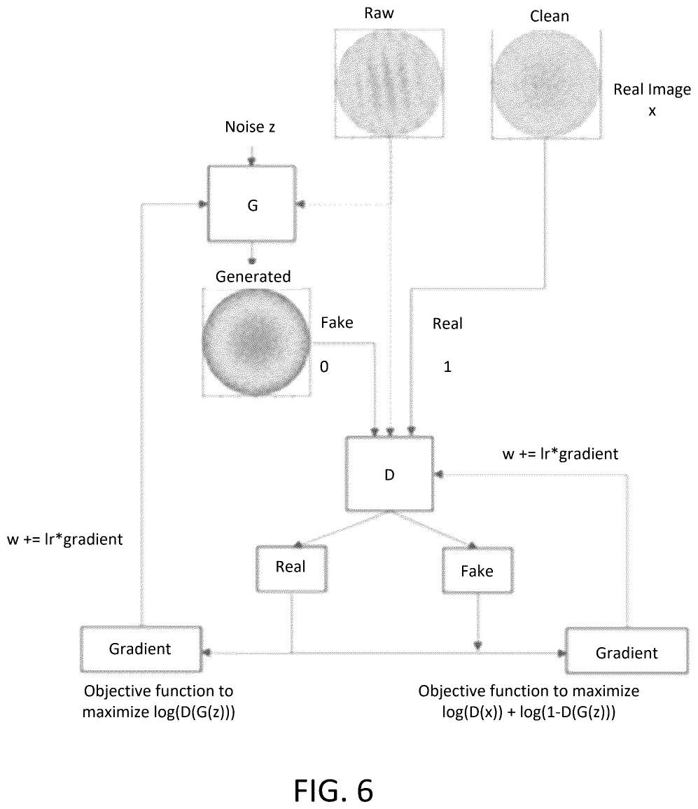

A flow chart and GAN is shown in FIG. 6. In an embodiment, the generator can be a 15-layer U-net with skip connections. There can be more than 54 million trainable parameters. In an instance, a sequence for the generator is Con2D, BatchNorm, ReLu, Con2DTrans, BatchNorm, Dropout 50%, Concat, and ReLu. In an embodiment, the discriminator can be a 6-layer CNN. There can be approximately 7 million trainable parameters. In an instance, a sequence for the discriminator can be Con2D, BatchNorm, ReLu. Other configurations are possible.

While many GAN architectures are possible, the GAN architecture can use a GAN model like that described in Isola et al., “Image-to-Image Translation with Conditional Adversarial Networks” (2018), which is incorporated by reference in its entirety. Pre-processing is added to convert workpiece data into a format where the GAN model can be used. Pre-processing can include value normalization, map resize (to nearest 2\hat{ }n), map reshape (from single channel to RGB 3 channel), and handling invalid pixels. Post-processing also is added. The post-processing may be a reverse of some of or all the steps of pre-processing.

Training typically uses pairs of (raw, clean) images. In an example, more than one thousand pairs of images may be used for training. The only difference between the two images in the pair may be presence of FPT. Real system FPT is generally only at a nanometer level height, while measurement drift/repeatability also is generally at a nanometer level. It can be difficult to create two identical maps only different in FPT by measurement. To resolve this problem, a data hybridization can use a clean image from direct measurement while the FPT error is generated using a Monte-Carlo simulation of the system. The final raw image can be reversely synthesized by the measured clean image and simulated FPT error.

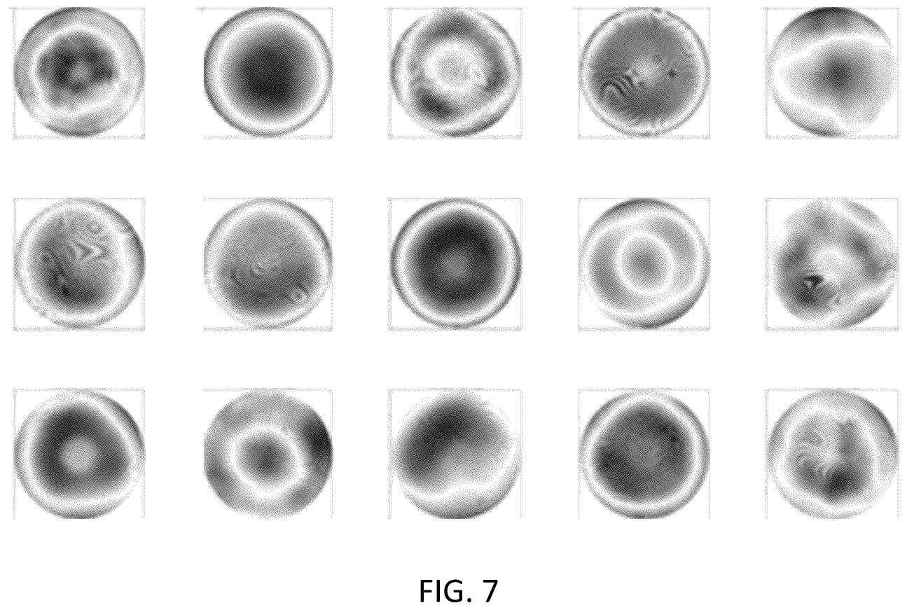

Data augmentation can be used to boost the number of training images, especially for rarer types of images. Besides common data augmentation methods such as rotation and flip, maps from different wafers/suppliers can be superimposed to get a pseudo wafer. Such superimposition is not applicable for general data augmentation purposes. For example, superimposing a dog image with a cat image will not give a meaningful image of an animal. However, it can be used on workpieces, like semiconductor wafers. For example, a thickness map may represent certain process control techniques such as CMP uniformity. Each workpiece has its signature map. Superimposing two thickness maps from different workpieces is equivalent to creating another set point in workpiece process control. Superimposing workpiece maps with different weights, together with other conventional data augmentation methods, can provide additional data for training. FIG. 7 shows some pseudo workpieces generated by superimposing different workpiece thickness maps at random weights. These are further superimposed with the artificial FPT via simulation. The large diversity of thickness maps is a result of the proposed superimposition data augmentation method. In FIG. 7, a diversified workpiece measurement pool of 680 workpieces (different source, different technology node, different tools) was established. Then five randomly selected workpieces were added up with a random weight (sum of weight equals 1) to get one superimposed pseudo wafer.

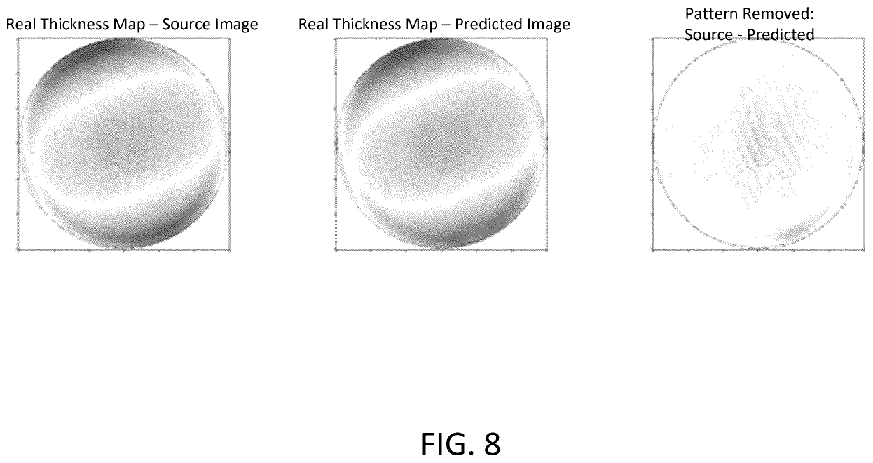

The FPT correction technique was demonstrated on wafer thickness maps under a noisy environment. FIG. 8 shows, from left to right, the source image fed into an embodiment of a trained model as disclosed herein, the output image predicted by the model, and the difference between the two to indicate what has been corrected. On the source image, obvious FPT can be seen especially in central area of wafer. In contrast, FPT is negligible on the predicted image. From the difference map, most of the pattern removed is in fringe pattern, even though at some small areas (e.g., bottom left area and extreme edge) there can be some over/under correction. Overall the method has demonstrated improved capability in FPT removal.

Embodiments of this neural network-based method may not separate phase error in FPT form or any true wafer features in similar wavy pattern. It will treat all such patterns on a wafer as error regardless of its cause. Thus, its correction can be based on phenomenon rather than reasoning from root cause.

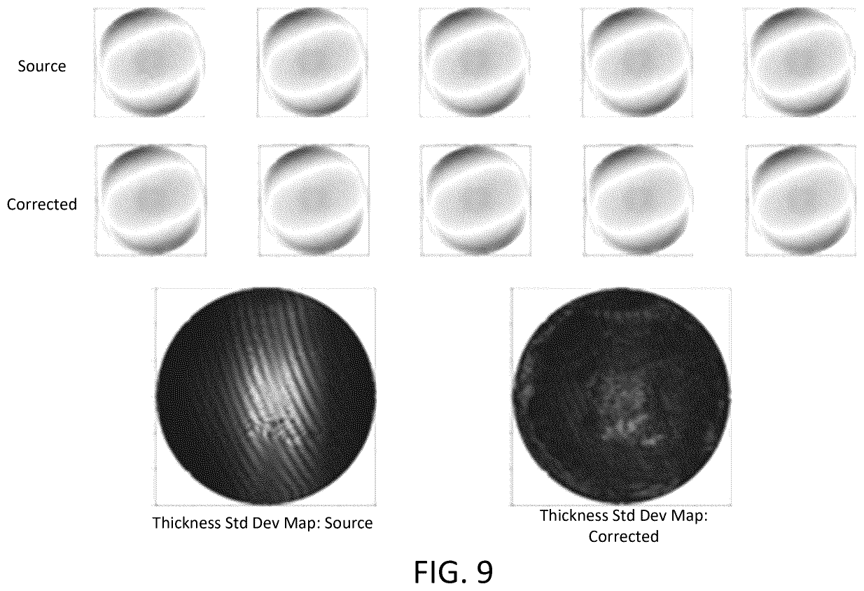

Precision (repeatability) and matching (accuracy) are two aspects of a metrology system. FIG. 9 is a demonstration of precision improvement. The top row is raw map of five independent measurements, which is a source to the model. The corresponding bottom map is a corrected map of a raw map from the top row. For both cases, the standard device of five measurements are calculated and plotted in the bottom row. The noise, which is in form of FPT, is largely suppressed after correction. The bottom two charts in FIG. 9 the standard deviation map (or noise map) to indicate precision improvement. The left one is standard deviation map of five measurements in top row (source). The right one is standard deviation map of five measurements in bottom row (corrected).

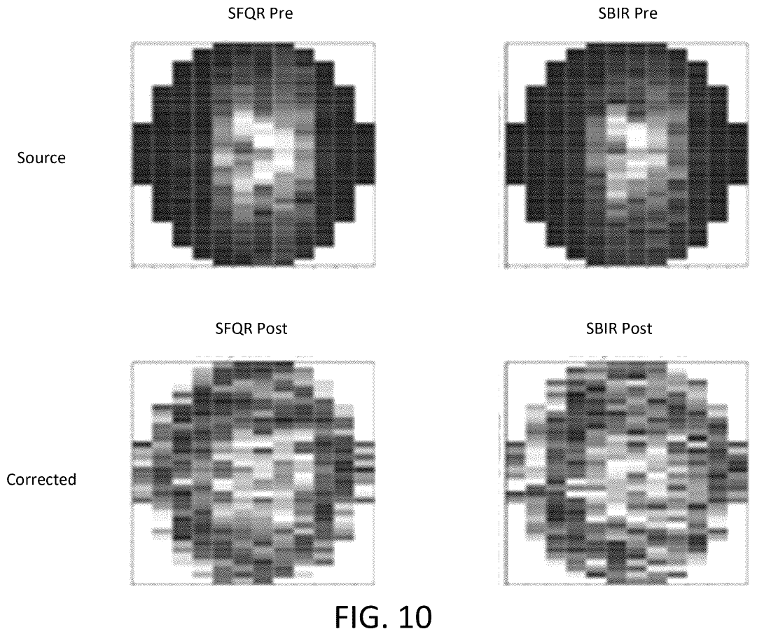

Besides map level precision improvement, flatness metrics can demonstrate better precision, as shown in FIG. 10 for SFQR and site back ideal focal plane range (SBIR). Take SBIR as an example, which is similar to SFQR. To get SBIR, a workpiece thickness map is divided into multiple sites. SBIR is the peak to valley (PV) value of this sites thickness. If FPT exists, the FPT may affect the PV and, consequently, SBIR. Removing the FPT reduces one noise source of SBIR and can improve its precision.

In FIG. 10, the source SFQR overall precision was 5.071 for the pre-processing example (“pre”) and the corrected SFQR was 1.239 for the post-processing example (“post”). In FIG. 10, the source SBIR overall precision was 4.435 for the pre-processing example (“pre”) and the corrected SBIR was 1.342 for the post-processing example (“post”).

In a first demonstration, a tool was operating in a noisy environment (enabled by a subwoofer shaking in-house) where precision is poor. This can test the model's resistivity to extreme cases. In a second demonstration, a tool was operating in a normal environment with a large variation of wafers. This can test the model's robustness to handle different wafer profiles.

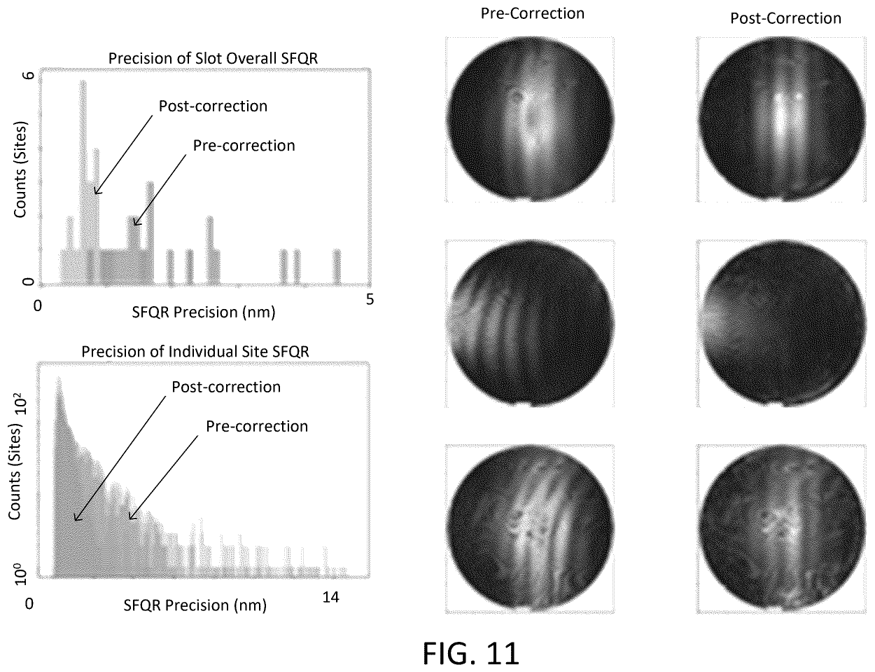

A precision histogram of the first demonstration in the noisy environment is shown in FIG. 11 for SFQR of whole wafer and an individual site. An improvement can be seen in both cases. Three precision maps are used as example to confirm reduction of FPT noise. The first histogram plot compares whole wafer SFQR pre-correction and post-correction. The second histogram plot compares all the available sites' SFQR with pre-correction and post-correction. Each wafer has 336 sites. The three pairs of precision maps compare flatness map precision pre-correction (left column) and post-correction (right column). Note that most or all of the FPT noise is removed during correction.

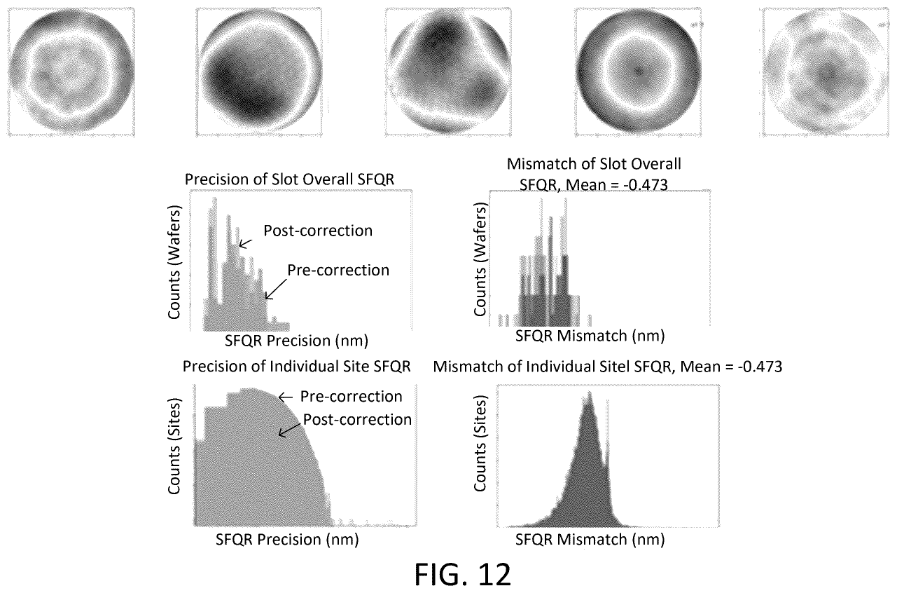

Results of the second demonstration with different wafer profiles under normal environmental conditions results are shown in FIG. 12. The first row provides examples of different wafer thickness profiles to show diversity. The second and third rows show an impact on SFQR precision/matching on a whole wafer and an individual site. Under normal environmental conditions, there is improvement in precision. There can be around 0.5 nm mismatch induced by the correction, which is within a specification for matching for SFQR (1 nm). The top row shows five example of pseudo wafer flatness maps and the histogram plots have the same convention as FIG. 11. For Precision of Slot Overall SFQR, the counts scale ranges from 0-25 and the SFQR precision scale ranges from 0.0 to 1.0 nm. For Precision of Individual Site SFQR, the counts scale ranges from 100 to more than 103 and the SFQR precision scale ranges from less than 10⁻¹ to 10² nm. For mismatch of slot overall SFQR, the counts scale ranges from 0-7 and the SFQR mismatch scale ranges from −1.00 to 1.00 nm. For mismatch of individual site SFQR, the counts scale ranges from 0-600 and the SFQR mismatch scale ranges from −2.00 to 2.00 nm.

Based on a statistical comparison of above two demonstrations, the correction can provide benefits to a semiconductor manufacturer with a metrology tool installed in a noisy fab where FPT error is high due to vibration. Under normal conditions, the tradeoff between improved precision and induced mismatch needs to be considered, even though the mismatch might be further reduced with some improvement on the model or additional pre-processing of data.

Using embodiments disclosed herein, phase error can be removed from images of a workpiece (e.g., semiconductor wafers). During operation, a workpiece on a stage in an interferometer is measured using the interferometer. An image of a surface of the workpiece is generated from the measurements using a processor. Phase error is removed from the image with a neural network. Such phase error can manifest as the fringes, such as those shown in FIG. 4.

In another embodiment, a non-transitory computer-readable storage medium can include one or more programs for executing the steps on one or more computing devices. Information about a surface of a workpiece (e.g., a semiconductor wafer) is received from an interferometer. An image of the surface of the workpiece is generated using the information. Phase error is then removed from the image with a neural network.

Although the present disclosure has been described with respect to one or more particular embodiments, it will be understood that other embodiments of the present disclosure May be made without departing from the scope of the present disclosure. Hence, the present disclosure is deemed limited only by the appended claims and the reasonable interpretation thereof.

What is claimed is:

1. An interferometer comprising:
a light source that generates a beam of light;
a beam splitter in a path of the beam of light;
a reference flat in a path of the beam of light from the beam splitter;
a stage configured to hold a workpiece in a path of the beam of light from the beam splitter;
a detector configured to receive light from the workpiece; and
a processor in electronic communication with the detector, wherein the processor is configured to run a neural network that removes phase error from an image generated using information from the detector.

2. The interferometer of claim 1, wherein the neural network is a generative adversarial network.

3. The interferometer of claim 1, wherein the workpiece is a semiconductor wafer.

4. A method comprising:
disposing a workpiece on a stage in an interferometer;
taking measurements of the workpiece using the interferometer; and
generating an image of a surface of the workpiece from the measurements using a processor; and
removing phase error from the image with a neural network operated using the processor.

5. The method of claim 4, wherein the neural network is a generative adversarial network.

6. The method of claim 4, wherein the workpiece is a semiconductor wafer.

7. The method of claim 4, wherein the neural network is trained using examples of two thickness maps superimposed on each other.

8. The method of claim 7, wherein the examples are measured using different tools.

9. A non-transitory computer-readable storage medium, comprising one or more programs for executing the following steps on one or more computing devices comprising:
receiving information about a surface of a workpiece from an interferometer;
generating an image of the surface of the workpiece using the information; and
removing phase error from the image with a neural network.

10. The non-transitory computer-readable storage medium of claim 9, wherein the neural network is a generative adversarial network.

11. The non-transitory computer-readable storage medium of claim 9, wherein the workpiece is a semiconductor wafer.

12. The non-transitory computer-readable storage medium of claim 9, wherein the neural network is trained using examples of two thickness maps superimposed on each other.

13. The non-transitory computer-readable storage medium of claim 12, wherein the examples are measured using different tools.
